(19) United States
(12) Patent Application Publication
(10) Pub. No.: US 2017/0139087 A1
(43) Pub. Date: May 18, 2017

(54) PLASMONIC OPTICAL FILTER

(71) Applicant: Commissariat à l'Énergie Atomique et aux Énergies Alternatives, Paris (FR)

(72) Inventors: Salim Boutami, Grenoble (FR); Jean-Jacques Yon, Sassenage (FR)

(73) Assignee: Commissariat à l'Énergie Atomique et aux Énergies Alternatives, Paris (FR)

(21) Appl. No.: 15/346,804

(22) Filed: Nov. 9, 2016

(30) Foreign Application Priority Data
Nov. 13, 2015 (FR) 15/60912

(51) Int. Cl. G02B 5/00; G01J 5/08; G02B 5/20; H01L 21/311; H01L 21/3205

(52) U.S. Cl. CPC G02B 5/008; H01L 21/31116; H01L 21/31144; H01L 21/32051; G02B 5/204; G01J 5/0862

(57) ABSTRACT

A plasmonic optical filter, including: a periodic repetition of metal slabs above a metal surface; dielectric spacers arranged between the slabs and the metal surface so that there exists an empty space between each slab and the metal surface; and an opening between each of said empty spaces and the outside.

### CROSS-REFERENCE TO RELATED APPLICATION

This application claims the priority to French patent application number 15/60912, filed Nov. 13, 2015, which is hereby incorporated by reference in its entirety to the maximum extent allowable by law.

### BACKGROUND

The present disclosure relates to optical filters, and more particularly to an optical filter using plasmonic resonators of MIM (metal-oxide-metal) type to selectively transmit or absorb an optical radiation.

### DISCUSSION OF THE RELATED ART

Optical filters with plasmonic resonators, or plasmonic filters, are used to selectively transmit or absorb an optical radiation having a selected wavelength. A plasmonic filter may for example be used in a bolometer to selectively absorb an infrared radiation. FIG. 1 is a perspective view of a plasmonic resonator arranged at the surface of a bolometer membrane 1, corresponding to FIG. 1 of “Multispectral microbolometers for the midinfrared”, T. Maier et Al., Optics Letters Vol. 35 N° 22, Nov. 15, 2010. The resonator comprises a metal layer 3 having a silicon nitride dielectric layer 5 covered with a square metal slab extending thereon. Dimension d of the slab sides is equal to λ/2n, λ designating the wavelength, and n designating an effective index of the plasmonic mode, close to the refraction index of layer 5.

The quality of the filtering is all the greater as the shape of the slab, which may be of submicron size, is accurately formed. Now, slabs of small size obtained by the available manufacturing techniques in reality have rounded angles and do not exactly have the desired dimensions. The quality of the obtained filtering is then altered.

### SUMMARY

Thus, an embodiment provides a plasmonic optical filter comprising a periodic repetition of metal slabs above a metal surface; dielectric spacers arranged between the slabs and the metal surface so that there exists an empty space between each slab and the metal surface; and an opening between each of said empty spaces and the outside.

According to an embodiment, the metal slabs are arranged in an array and have the shape of squares with sides having a dimension in the range from 0.3 μm to 3 μm.

According to an embodiment, the metal slabs have a thickness in the range from 30 nm to 100 nm and the dielectric spacers have a thickness in the range from 30 nm to 300 nm.

According to an embodiment, the dielectric spacers form a grid delimiting said empty spaces, the entire periphery of each slab being arranged on the grid, and said opening being formed in each slab.

According to an embodiment, the openings have diameters in the range from 10 to 40 nm.

According to an embodiment, the grid delimits square empty spaces.

According to an embodiment, the grid delimits circular empty spaces.

According to an embodiment, the dielectric spacers are pads arranged in an array, each slab having four corners arranged on four neighboring pads, the openings being spaces between the slabs.

According to an embodiment, the dielectric spacers are bar-shaped, each slab having two edges arranged on two neighboring bars, the openings being spaces between the slabs.

An embodiment provides a method of forming a plasmonic optical filter on a metal surface, comprising the steps of:

a) depositing a dielectric layer on the metal surface;

b) forming, on the dielectric layer, a periodic repetition of separate metal slabs, each of which is provided with an opening; and

c) removing a portion of the dielectric layer by selective isotropic etching from the openings, to form empty spaces under each metal slab.

According to an embodiment, the method comprises, between step b) and step c), a step of masking the portions of the dielectric layer accessible between the metal slabs.

According to an embodiment, the dielectric layer is made of silicon oxide.

An embodiment provides a method of forming a plasmonic optical filter on a metal surface, comprising the steps of:

a) forming a periodic repetition of dielectric spacers on the metal surface;

b) filling with a sacrificial material the entire volume between the spacers;

c) forming a periodic repetition of separate metal slabs, each slab mostly resting on the sacrificial material; and

d) selectively etching the sacrificial material from the openings between the separate metal slabs.

According to an embodiment, the dielectric spacers are made of silicon oxide, the sacrificial material is silicon nitride, and the selective etching is a RIE etching in a SF₆ and oxygen medium.

According to an embodiment, the dielectric spacers are made of silicon, the sacrificial material is silicon oxide, and the selective etching is a RIE etching under a CF₄ and oxygen plasma.

According to an embodiment, the dielectric spacers are made of silicon oxide, the sacrificial material is silicon, and the selective etching is a RIE etching under a BCl₃, Cl₂ and nitrogen plasma or a dry etching under xenon difluoride (XeF₂).

According to an embodiment, the dielectric spacers are made of aluminum oxide, the sacrificial material is silicon oxide, and the selective etching is a chemical vapor etching with hydrofluoric acid.

An embodiment provides a bolometer comprising a filter such as hereabove.

The foregoing and other features and advantages will be discussed in detail in the following non-limiting description of dedicated embodiments in connection with the accompanying drawings.

### BRIEF DESCRIPTION OF THE DRAWINGS

FIG. 1 is a perspective view of a plasmonic resonator;

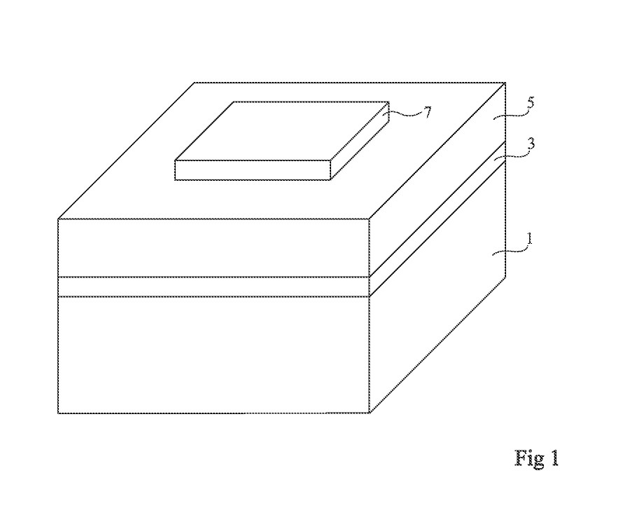

FIGS. 2A to 2D illustrate steps of a method of forming a plasmonic optical filter;

FIG. 3 illustrates the absorption according to the wavelength by the optical filter of FIG. 2D;

FIG. 4 is a partial perspective cross-section view of a variation of a plasmonic optical filter;

FIGS. 5A to 5D illustrate steps of a method of forming another variation of a plasmonic optical filter;

FIG. 6 illustrates the absorption according to the wavelength by the optical filter of FIG. 5D; and

FIG. 7 is a partial perspective cross-section view of another variation of a plasmonic optical filter.

### DETAILED DESCRIPTION

The same elements have been designated with the same reference numerals in the different drawings and, further, the various drawings are not to scale. For clarity, only those elements which are useful to the understanding of the described embodiments have been shown and are detailed.

In the following description, when reference is made to terms qualifying a relative position, such as term “top”, “bottom”, “upper”, “on”, “under”, reference is made to the orientation of the concerned element in the drawings. Unless otherwise specified, expression “in the order of” means to within 10%, preferably to within 5%.

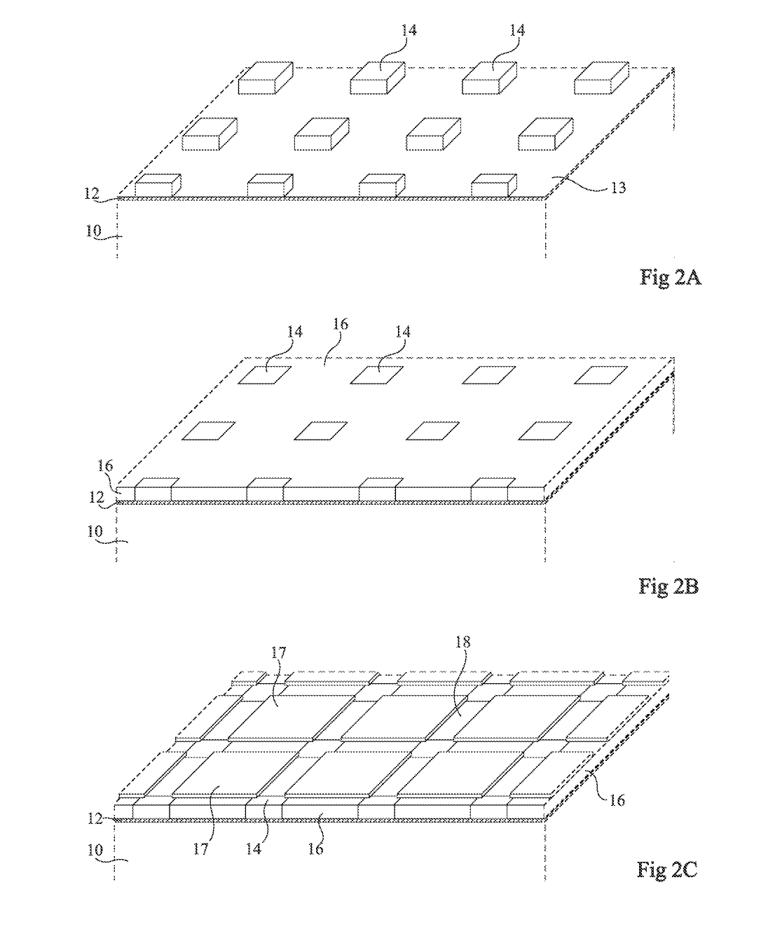

FIGS. 2A to 2D are partial perspective cross-section views illustrating steps of a method of forming a plasmonic optical filter. The plasmonic filter is formed on a support 10 having a metallic upper surface 13, for example, a bolometer membrane covered with a metal layer 12.

At the step illustrated in FIG. 2A, dielectric pads 14 are formed on metal surface 13 of support 10. Pads 14 have a square shape and are arranged in an array. Pads 14 are for example formed by lithography.

At the step illustrated in FIG. 2B, the space between pads is filled with a sacrificial material 16, pads 14 being flush with the upper surface of sacrificial material 16. To perform this filling, a layer of sacrificial material may be deposited on metal surface 13 and on the pads, after which the upper surface of the assembly may be polished at least all the way to the level of pads 14 to obtain a planar surface.

At the step illustrated in FIG. 2C, separate metal square slabs 17 are formed on the upper surface of the assembly, for example, by lithography. The corners of each slab are arranged on four neighboring pads 14, the slab mostly resting on sacrificial material 16. The slab thus obtained is regular, and the slabs are separated by spacings 18.

FIG. 2D shows the plasmonic optical filter 19 obtained after a step of removing sacrificial material 16 by selective etching. Each slab is held by the pads located on its corners and the most part of each slab is suspended above an empty space 20. Pads 14 have the function of spacers enabling to keep empty space 20.

As previously indicated, dimension d of the slab sides is equal to λ/2n, λ designating the wavelength, and n designating the refraction index of the material located under each slab. Now, n is now equal to 1 under the most part of each slab. Thereby, for a given filtering wavelength, slabs 17 may be up to n times larger than in the case where these slabs rest on a dielectric material. n is for example close to 1.45 for silicon oxide and close to 2 for silicon nitride. For larger slabs, the shapes are formed with a better accuracy, and filter 19 of FIG. 2D has a better accuracy as to the position of the obtained filtering peak relative to the one which is desired.

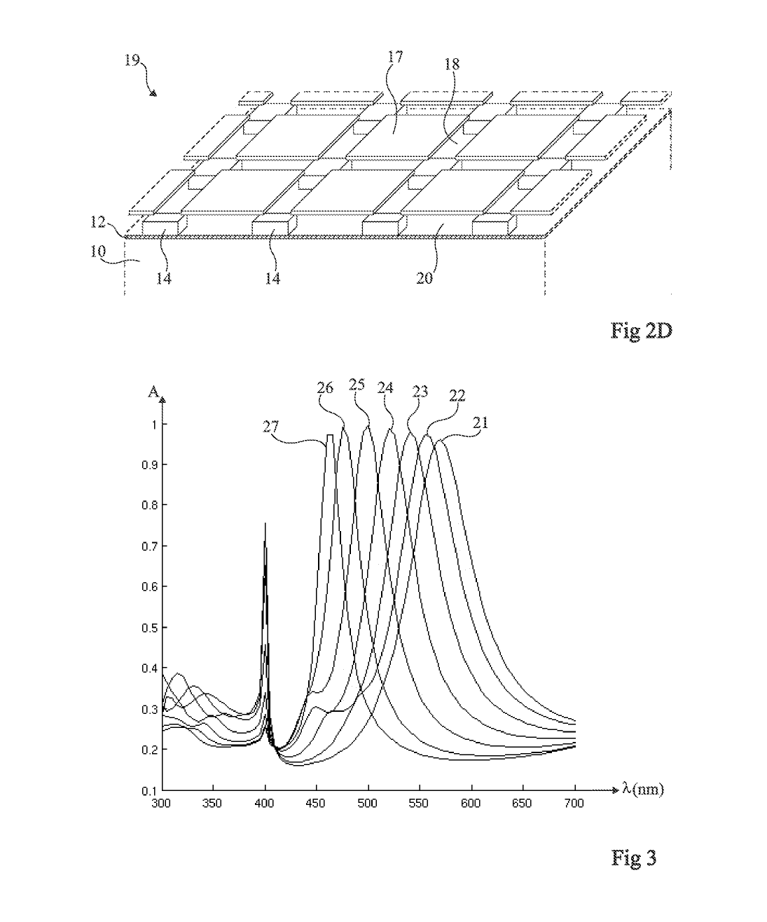

FIG. 3 shows curves 21 to 27 illustrating absorption A of an optical radiation by embodiments of filters according to the method of FIGS. 2A to 2D, according to wavelength λ of the radiation. The filters only differ by the dimensions of their pads 14, slabs 17 being identical with identical spacings 18. The filter associated with curve 21 has the largest pads 14 and accordingly the smallest empty spaces 20. The filter associated with curve 27 conversely has the smallest pads 14, empty spaces 20 being the largest. It can be observed that with slabs of same dimensions, a radiation having a wavelength all the smaller as empty spaces 20 under the pads are large can be filtered.

As an example, metal layer 12 and metal slabs 17 are made of aluminum. Pads 14 may be made of silicon oxide and the sacrificial material may be silicon nitride, the selective etching of the sacrificial layer can then be performed by reactive ion etching or RIE in a SF₆ and oxygen medium. In a variation, pads 14 are made of polysilicon, the sacrificial material is silicon oxide, and the selective etching is a RIE etching under a CF₄ and oxygen plasma. In another variation, pads 14 are made of silicon oxide, the sacrificial material is polysilicon, and the selective etching is a RIE etching under a BCl₃, Cl₂ and nitrogen plasma or a dry etching under xenon difluoride (XeF₂). In another variation, the pads are made of aluminum oxide, the sacrificial material is silicon oxide, and the selective etching is a chemical vapor etching with hydrofluoric acid. More generally, any combination of two materials to which a selective etch method can be adapted may be selected for the pads and the sacrificial material.

As an example, dimension d of the sides of the slabs has a length in the range from 0.2 μm to 3 μm, respectively corresponding to a wavelength in the range from 0.4 to 6 μm.

The slab thickness may be in the range from 20 to 100 nm. The thickness or height of the pads may be in the range from 30 to 300 nm.

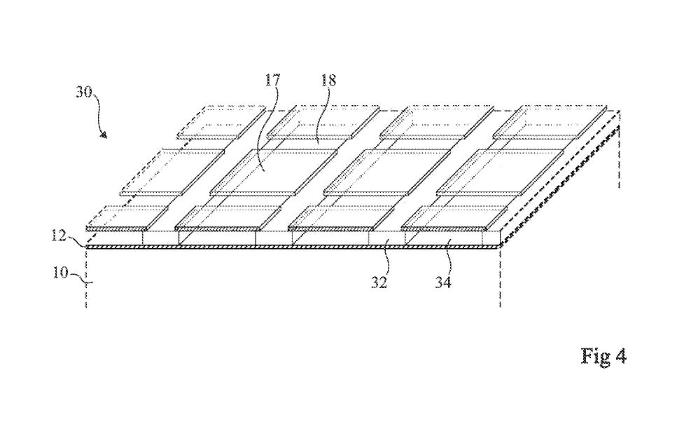

FIG. 4 is a partial perspective cross-section view of a variation of a plasmonic optical filter 30. Optical filter 30 corresponds to filter 19 of FIG. 2D where pads 14 have been replaced with parallel bars 32. Each slab 17 forms a bridge above the empty space 34 located between two bars.

Each slab 17 of filter 30 is held by two sides, which provides a better mechanical resistance than that of the slabs of filter 19 of FIG. 2D which are only held by their corners. Such a mechanical resistance is advantageous since the device may be submitted to thermal expansions, to pressures, or to vibrations, which may damage the slabs. There however is a sensitivity to biasing in this embodiment, since the structure no longer has the 90° rotational symmetry.

It should be noted that the empty spaces located under slabs 17 of filter 30, as well as under slabs 17 of filter 19 of FIG. 2D, are open towards the outside by spacings 18 between the separate slabs. Thus, in a pressure or temperature variation, the gas present in the empty space under the slabs may freely enter or escape, which avoids adverse mechanical stress.

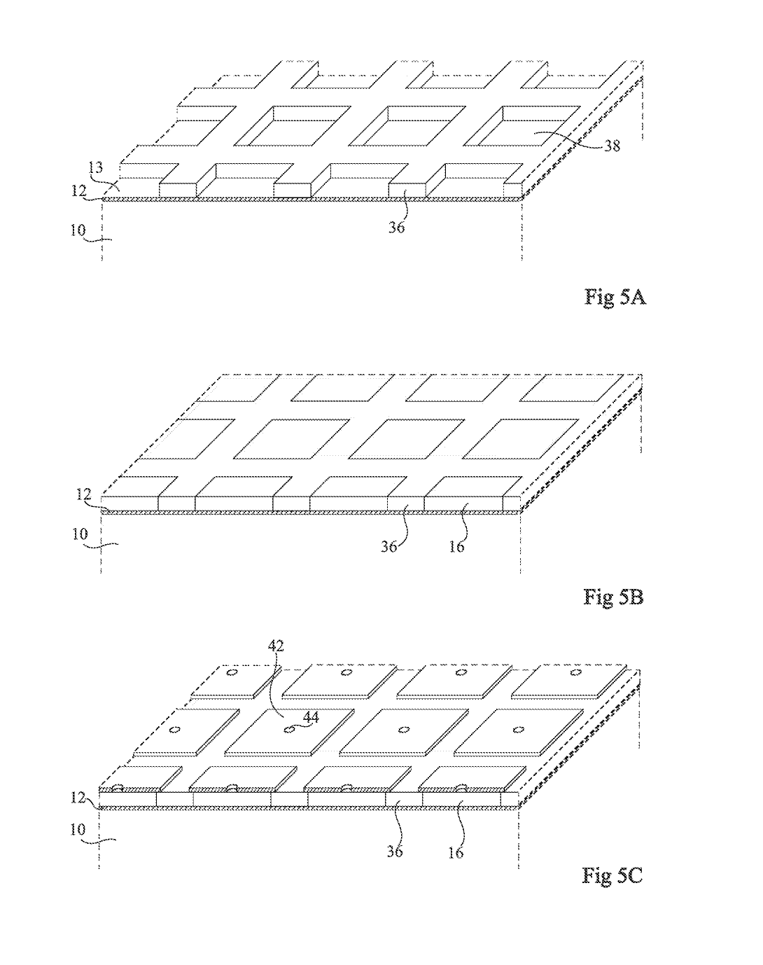

FIGS. 5A to 5D are partial perspective cross-section views illustrating steps of a method of forming another variation of a plasmonic filter on metal surface 13 of a support 10.

The step illustrated in FIG. 5A corresponds to the step of FIG. 2A, pads 14 of FIG. 2A having been replaced with a grid-shaped structure 36 delimiting square spaces 38.

The step illustrated in FIG. 5B corresponds to the step of FIG. 2B. Spaces 38 are filled with a sacrificial material 16.

The step illustrated in FIG. 5C corresponds to the step of FIG. 2C. Separate square metal slabs 42 are formed on the upper surface of the assembly and form a regular paving. Each slab 42 covers the sacrificial material located in a space 38 and the periphery of each slab is entirely located on grid 36.

Each slab 42 is provided with an opening 44, for example located at the center of the slab.

FIG. 5D shows the optical filter 46 obtained after a step of selectively etching sacrificial material 16 from openings 44. The most part of each slab is located above an empty space 38.

Each empty space 38 communicates with the outside through opening 44 in the slab. As previously indicated, the communication openings enable the filter to mechanically withstand pressure variations. Further, each slab is now held along its entire periphery. This feature advantageously provides mechanical filter 46 with a remarkably increased mechanical resistance. Further, this embodiment keeps the insensitivity to biasing, since the structure keeps the 90° rotational symmetry (if the x and y periods are equal).

The openings may have any shape. As an example, openings 44 are circular, with diameters in the range from 10 to 40 nm. The inventors have observed that the presence of such openings 44 has a negligible effect on the optical properties of the filter.

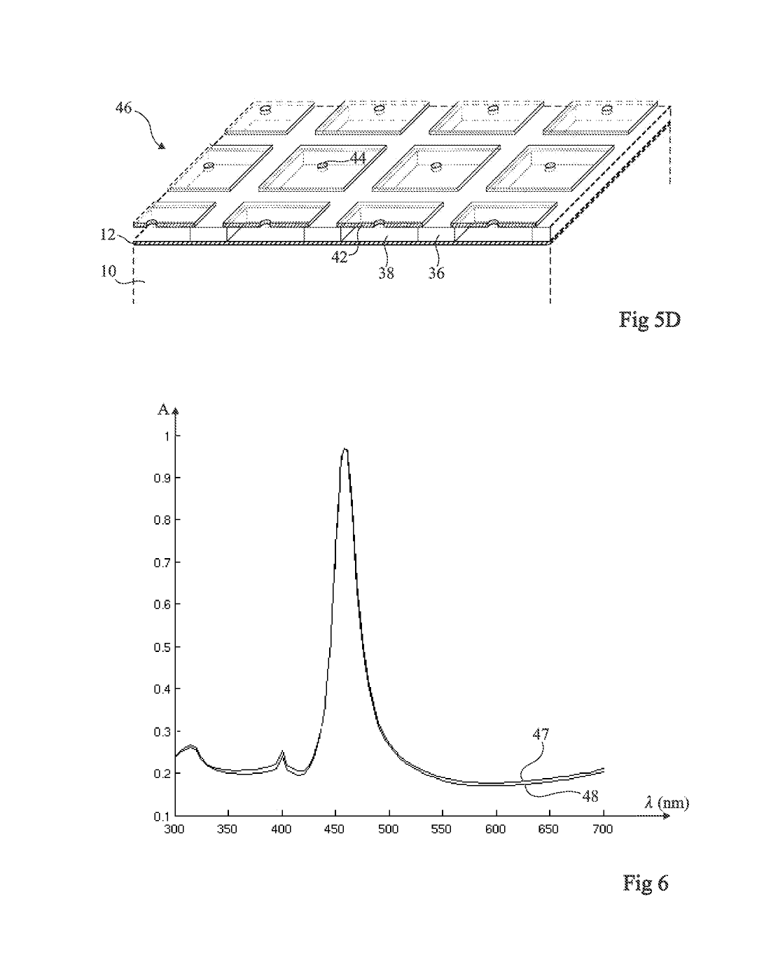

This is shown in FIG. 6, which illustrates simulation results. Absorption 47 of an optical radiation by a filter 46 is compared with absorption 48 by an identical filter where the slabs would comprise no openings. The presence in filter 46 of circular openings 44 having diameters reaching 40 nm in slabs having 300-nm sides only increases by less than 2% the interval of absorbed wavelengths. With all the more reason, smaller openings in larger slabs have even lesser effects.

Filter 46 has an optical quality identical to that of filters 19 and 30 of FIGS. 2D and 4, and withstands pressure variations just as well, while being provided with a remarkably increased mechanical resistance. Further, the insensitivity to biasing is kept.

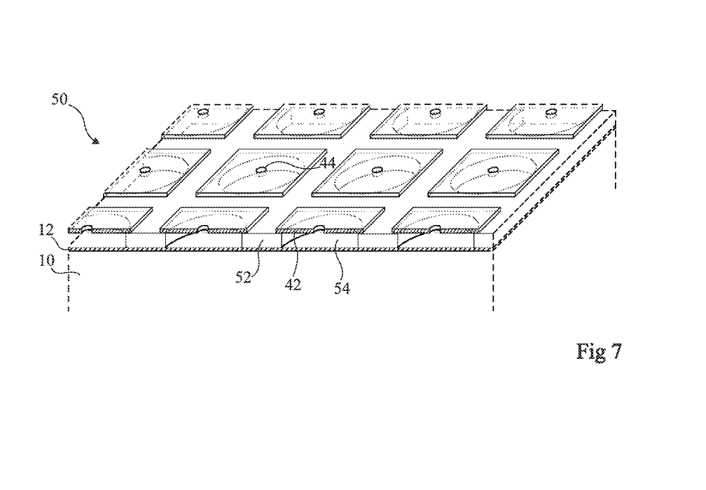

FIG. 7 is a partial perspective cross-section view of another variation of a plasmonic optical filter 50.

Optical filter 50 is formed by forming, on a uniform layer of a dielectric material 52 covering metal surface 13 of a support 10, a regular paving of separate square metal slabs 42. Each slab is provided with a central opening 44. Dielectric material 52 is then selectively etched, isotropically, from openings 44 to form an empty space 54 under the most part of each of slabs 42. The etching may be performed after a masking intended to protect the portions of dielectric material 52 accessible between the slabs. The obtained filter 50 corresponds to filter 46 of FIG. 5D, where square empty spaces 38 have been replaced with circular empty spaces 54. The remaining dielectric material 52 forms a grid-shaped structure delimiting circular spaces. As an example, dielectric material 52 may be silicon oxide.

Filter 50 has the advantage that it can be formed in a very simple way.

Specific embodiments have been described. Various alterations, modifications, and improvements will occur to those skilled in the art. In particular, metal surface 13 of the described embodiments is a continuous surface on which the formed plasmonic filters are reflection filters, that is, filters absorbing an optical radiation having a selected wavelength and reflecting the optical radiations of other wavelengths. Variations of plasmonic filters transmitting a radiation of selected wavelength are possible, where the metal support comprises separate metal slabs formed on a transparent support.

Further, although the slabs of the above-described embodiments are square-shaped, the slabs may have other shapes capable of forming plasmonic resonators. As an example, the slabs may be cross-shaped or round. As a variation, the slabs may have rectangular shapes to favor the filtering of radiations having a selected biasing.

Further, although in the described embodiments, the slabs are arranged in an array, the slabs may be periodically repeated according to other configurations. For example, the slabs may be arranged in a triangular network.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A plasmonic optical filter comprising:
a periodic repetition of metal slabs above a metal surface;
dielectric spacers arranged between the slabs and the metal surface so that there exists an empty space between each slab and the metal surface; and
an opening between each of said empty spaces and the outside.

2. The filter of claim 1, wherein the metal slabs are arranged in an array and have the shape of squares with sides having a dimension in the range from 0.3 μm to 3 μm.

3. The filter of claim 1, wherein the metal slabs have a thickness in the range from 30 nm to 100 nm and the dielectric spacers have a thickness in the range from 30 nm to 300 nm.

4. The filter of claim 1, wherein the dielectric spacers form a grid delimiting said empty spaces, the entire periphery of each slab being arranged on the grid, and said opening being formed in each slab.

5. The filter of claim 1, wherein the openings have diameters in the range from 10 to 40 nm.

6. The filter of claim 4, wherein the grid delimits square empty spaces.

7. The filter of claim 4, wherein the grid delimits circular empty spaces.

8. The filter of claim 1, wherein the dielectric spacers are pads arranged in an array, each slab having four corners arranged on four neighboring pads, the openings being spaces between the slabs.

9. The filter of claim 1, wherein the dielectric spacers are bar-shaped, each slab having two edges arranged on two neighboring bars, the openings being spaces between the slabs.

10. A method of forming a plasmonic optical filter on a metal surface, comprising the steps of:
a) depositing a dielectric layer on the metal surface;
b) forming, on the dielectric layer, a periodic repetition of separate metal slabs, each of which is provided with an opening; and
c) removing a portion of the dielectric layer by selective isotropic etching from the openings, to form empty spaces under the most part of each metal slab.

11. The method of claim 10, comprising, between step b) and step c), a step of masking the portions of the dielectric layer accessible between the metal slabs.

12. The method of claim 10, wherein the dielectric layer is made of silicon oxide.

13. A method of forming a plasmonic optical filter on a metal surface, comprising the steps of:
a) forming a periodic repetition of dielectric spacers on the metal surface;
b) filling with a sacrificial material the entire volume between the spacers;
c) forming a periodic repetition of separate metal slabs, each slab mostly resting on the sacrificial material; and
d) selectively etching the sacrificial material from the openings between the separate metal slabs.

14. The method of claim 13, wherein the dielectric spacers are made of silicon oxide, the sacrificial material is silicon nitride, and the selective etching is a RIE etching in a SF₆ and oxygen medium.

15. The method of claim 13, wherein the dielectric spacers are made of silicon, the sacrificial material is silicon oxide, and the selective etching is a RIE etching under a CF₄ and oxygen plasma.

16. The method of claim 13, wherein the dielectric spacers are made of silicon oxide, the sacrificial material is silicon, and the selective etching is a RIE etching under a BCl₃, Cl₂ and nitrogen plasma or a dry etching under xenon difluoride (XeF₂).

17. The method of claim 13, wherein the dielectric spacers are made of aluminum oxide, the sacrificial material is silicon oxide, and the selective etching is a chemical vapor etching with hydrofluoric acid.

18. A bolometer comprising the filter of claim 1.
